(19) United States
(12) Patent Application Publication
(10) Pub. No.: US 2025/0072267 A1
(43) Pub. Date: Feb. 27, 2025

(54) ANTI-REFLECTIVE FILM STRUCTURE

(71) Applicant: Sichuan Longhua Film Co., Ltd., Mianyang City (CN)

(72) Inventors: RUIMIN DIAO, Mianyang City (CN); YAO-CHANG WANG, Zhubei City (TW)

(21) Appl. No.: 18/811,528

(22) Filed: Aug. 21, 2024

(30) Foreign Application Priority Data
Aug. 25, 2023 (CN) 202311088881.2

(51) Int. Cl. H10K 59/80; G02B 1/118

(52) U.S. Cl. CPC H10K 59/8791; G02B 1/118

(57) ABSTRACT

An anti-reflective film structure includes a λ/4 phase difference compensation film, a λ/2 phase difference compensation film, and a linear polarizer. The λ/4 phase difference compensation film and the λ/2 phase difference compensation film have positive wavelength dispersion. One of the λ/4 phase difference compensation film and the λ/2 phase difference compensation film is a positive A-plate, and the other one is a negative A-plate. The λ/4 phase difference compensation film is arranged on an OLED display panel, the λ/2 phase difference compensation film is arranged on a side of the λ/4 phase difference compensation film away from the OLED display panel, and the linear polarizer is arranged on a side of the λ/2 phase difference compensation film away from the λ/4 phase difference compensation film. The stacked positive A-plate and negative A-plate have λ/4 inverse wavelength dispersion and viewing angle compensation characteristics.

### FIELD OF THE INVENTION

The present invention relates to an anti-reflective film structure, and particularly relates to an anti-reflective film structure adapted to be applied to an organic light-emitting diode (OLED) display panel.

### BACKGROUND OF THE INVENTION

Usually, a common active-matrix organic light-emitting diode (AMOLED) display requires a quarter-wave (λ/4) compensation film with a large viewing angle and a wide wavelength domain between a linear polarizer and an organic light-emitting diode display panel, to compensate for the problems of reduced contrast caused by light leakage at front and wide viewing angles, poor readability under ambient light, and black images not being dark enough.

A conventional compensation film with a large viewing angle and a wide wavelength domain mainly includes a positive A-plate and a positive C-plate. The positive A-plate is an inverse wavelength dispersed λ/4 compensation film (quarter-wave film (QWF)) while the positive C-plate serves as a compensation film with a large viewing angle. An in-plane phase difference (R₀) of the film needs to be as small as possible, and R₀ is less than 10 best. A thickness direction phase difference (Rₜₕ) needs to match with the positive A-plate to compensate the large viewing angle. However, the current inverse dispersed positive A-plate of a one-piece λ/4 compensation film is made of a special material, which has the problems that it is relatively expensive, and the inverse dispersion characteristic is far from the ideal inverse dispersion characteristic. The positive C-plate is usually manufactured by a liquid crystal coating process, which also has shortcomings of poor process yield, poor reliability, and the like.

### SUMMARY OF THE INVENTION

The present invention provides an anti-reflective film structure, which has the advantages that characteristics of a large viewing angle and a wide wavelength domain are satisfied, and the yield of a product is high.

The present invention provides an anti-reflective film structure, adapted to be applied to an organic light-emitting diode display panel. The anti-reflective film structure includes a quarter-wave (λ/4) phase difference compensation film, a half-wave (λ/2) phase difference compensation film, and a linear polarizer. The λ/4 phase difference compensation film has positive wavelength dispersion, is selected from one of the positive A-plate and the negative A-plate, and is arranged on the organic light-emitting diode display panel; the λ/2 phase difference compensation film has positive wavelength dispersion, is selected from the other one of the positive A-plate and the negative A-plate, and is arranged on a side of the λ/4 phase difference compensation film away from the organic light-emitting diode display panel; and the linear polarizer is arranged on a side of the λ/2 phase difference compensation film away from the λ/4 phase difference compensation film.

In an embodiment of the present invention, the λ/2 phase difference compensation film has a first optical axis angle, the λ/4 phase difference compensation film has a second optical axis angle, and the first optical axis angle is different from the second optical axis angle. In an embodiment, the first optical axis angle is between 10° and 20°, and the second optical axis angle is between 70° and 80°, or the first optical axis angle is between 70° and 80°, and the second optical axis angle is between 100 and 200.

In an embodiment of the present invention, an in-plane phase difference (R₀) of the λ/4 phase difference compensation film is between 90 nanometers and 140 nanometers, and an in-plane phase difference (R₀) of the λ/2 phase difference compensation film is between 180 nanometers and 280 nanometers.

In an embodiment of the present invention, the anti-reflective film structure further includes a plurality of optical adhesive layers respectively arranged between the λ/4 phase difference compensation film and the organic light-emitting diode display panel, between the λ/4 phase difference compensation film and the λ/2 phase difference compensation film, and between the λ/2 phase difference compensation film and the linear polarizer.

In an embodiment of the present invention, a material of the optical adhesive layer is selected from one of an optically clear adhesive (OCA), a liquid optically clear adhesive (LOCA), and a pressure sensitive adhesive (PSA) or a combination thereof.

In an embodiment of the present invention, the positive A-plate has a first thickness direction phase difference, the negative A-plate has a second thickness direction phase difference, and the sum of the first thickness direction phase difference and the second thickness direction phase difference is less than 10.

In an embodiment of the present invention, a thickness of each of the positive A-plate and the negative A-plate is between 10 microns (μm) and 40 microns (μm).

In an embodiment of the present invention, each of the positive A-plate and the negative A-plate is manufactured by a stretching process.

In an embodiment of the present invention, the stacked positive A-plate and negative A-plate have quarter-wave inverse wavelength dispersion, match with the linear polarizer, and are applied to the organic light-emitting diode display panel, so that reflectivity is between 0.5% and 2.0%.

In the present invention, the positive A-plate and the negative A-plate are combined to form the double-layered compensation film with the large viewing angle and the wide wavelength domain, which is combined with the linear polarizer to form the anti-reflective film structure, wherein the positive A-plate and the negative A-plate are arranged between the organic light-emitting diode display panel and the linear polarizer.

### BRIEF DESCRIPTION OF THE DRAWINGS

The present invention will become more readily apparent to those ordinarily skilled in the art after reviewing the following detailed description and accompanying drawings, in which:

FIG. 1 is a sectional schematic diagram of an anti-reflective film structure according to an embodiment of the present invention; and

FIG. 2 is a schematic diagram of a dispersion curve of the anti-reflective film structure according to an embodiment of the present invention.

### DETAILED DESCRIPTION OF PREFERRED EMBODIMENTS

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

Terms and symbols in the description are defined below.

(1) Thickness direction phase difference (Rₜₕ): at 23° C., the phase difference in the thickness direction is measured with incident light with a specific wavelength. For example, Rₜₕ(550) represents the phase difference in the thickness direction is measured with incident light with the wavelength of 550 nm at 23° C., which satisfies the equation I:

Rₜₕ(X)=[(nₓ+n_{y})/2−n_{z}]×d (Equation I),
where n is a refractive index; nₓ, n_{y}, and n_{z} respectively represent refractive indexes of a slow axis, a fast axis and the thickness direction; and d represents a thickness (nm).

(2) In-plane phase difference (R₀): at 23° C., the phase difference in a plane is measured with incident light with the specific wavelength. For example, R₀(550) represents the phase difference in the plane is measured with incident light with the wavelength of 550 nm at 23° C., which satisfies the equation II:

R₀(λ)=(nₓ−n_{y})×d (Equation II),
where nₓ, n_{y}, and d are defined as above.

(3) Positive wavelength dispersion: with increase of the wavelength of the incident light, the corresponding in-plane phase difference decreases; usually, based on the incident light with the wavelength of 550 nm, the positive wavelength dispersion satisfies the equation III:

R₀(450)/R₀(550)>R₀(650)/R₀(550) (Equation III)

(4) Inverse wavelength dispersion: with increase of the wavelength of the incident light, the corresponding in-plane phase difference increases; usually, based on the incident light with the wavelength of 550 nm, the positive wavelength dispersion satisfies the equation IV:

R₀(450)/R₀(550)<R₀(650)/R₀(550) (Equation IV)

(5) A-plate: according to a relationship among the refractive indexes nₓ, n_{y} and n_{z}, the A-plate can be divided into the positive A-plate and the negative A-plate; the positive A-plate satisfies the relationship of nₓ>n_{y}−n_{z}; and the negative A-plate satisfies the relationship of nₓ<n_{y}*n_{z}.

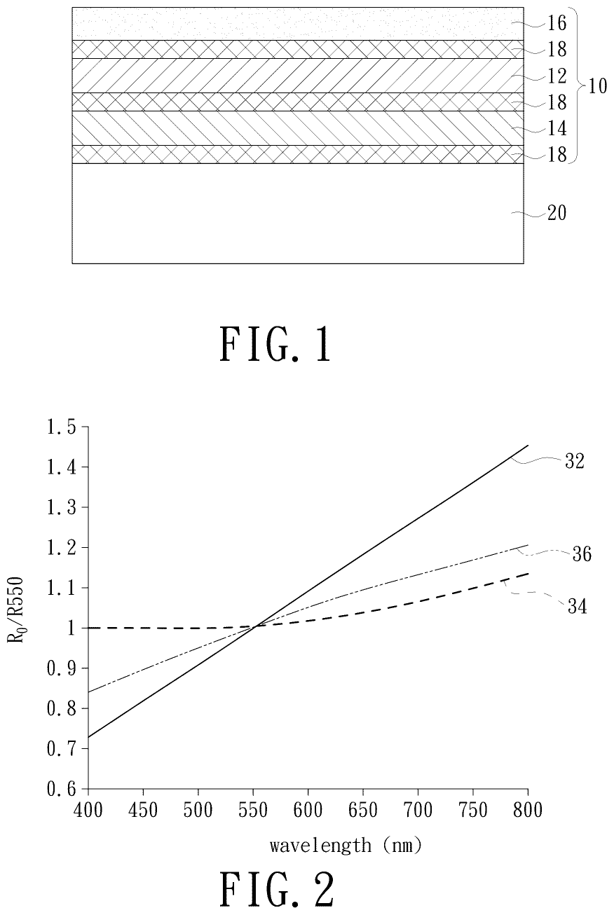

FIG. 1 is a sectional schematic diagram of an anti-reflective film structure according to an embodiment of the present invention. As shown in the FIG. 1, the anti-reflective film structure 10 is adapted to be applied to an organic light-emitting diode display panel 20. The anti-reflective film structure 10 includes a quarter-wave (λ/4) phase difference compensation film 14, a half-wave (λ/2) phase difference compensation film 12, and a linear polarizer 16, wherein the λ/4 phase difference compensation film 14 and the λ/2 phase difference compensation film 12 both have positive wavelength dispersion; one of the λ/4 phase difference compensation film 14 and the λ/2 phase difference compensation film is a positive A-plate and the other one of the λ/4 phase difference compensation film and the λ/2 phase difference compensation film is a negative A-plate. The λ/4 phase difference compensation film 14 is arranged on the organic light-emitting diode display panel 20, the λ/2 phase difference compensation film 12 is arranged on a side of the λ/4 phase difference compensation film 14 away from the organic light-emitting diode display panel 20, and further, the linear polarizer 16 is arranged on a side of the λ/2 phase difference compensation film 12 away from the λ/4 phase difference compensation film 14.

Specifically speaking, when the λ/2 phase difference compensation film 12 is, for example, the positive A-plate, and the λ/4 phase difference compensation film 14 is the negative A-plate, so that the organic light-emitting diode display panel 20, the negative A-plate, the positive A-plate, and the linear polarizer 16 are arranged in sequence. Correspondingly, when the λ/2 phase difference compensation film 12 is, for example, the negative A-plate, and the λ/4 phase difference compensation film 14 is the positive A-plate, so that the organic light-emitting diode display panel 20, the positive A-plate, the negative A-plate, and the linear polarizer 16 are arranged in sequence.

In an embodiment, the λ/2 phase difference compensation film 12 has a first optical axis angle (θ₁), the λ/4 phase difference compensation film 14 has a second optical axis angle (θ₂), and the first optical axis angle is different from the second optical axis angle (θ₁:θ₂), which satisfies the equation V:

$${θ}_{1} + {θ}_{2} = 90 ° \qquad ( Equation V )$$

For example, when the first optical axis angle is 15°, the second optical axis angle is 75°; or when the first optical axis angle is 75°, the second optical axis angle is 15°. Here, the first optical axis angle (θ₁) is, for example, the angle between a fast axis of the λ/2 phase difference compensation film 12 and a transmission axis of the linear polarizer 16, and the second optical axis angle (θ₂) is, for example, the angle between a fast axis of the λ/4 phase difference compensation film 14 and the transmission axis of the linear polarizer 16.

In an embodiment, an in-plane phase difference (R₀) of the λ/4 phase difference compensation film 12 is 125 nm, and an in-plane phase difference (R₀) of the λ/2 phase difference compensation film 14 is 250 nm.

In an embodiment, the anti-reflective film structure 10 further includes a plurality of optical adhesive layers 18 respectively arranged between the λ/4 phase difference compensation film 14 and the organic light-emitting diode display panel 20, between the λ/4 phase difference compensation film 14 and the λ/2 phase difference compensation film 12, and between the λ/2 phase difference compensation film 12 and the linear polarizer 16, wherein a material of the optical adhesive layer 18 is selected from one of an optically clear adhesive (OCA), a liquid optically clear adhesive (LOCA), and a pressure sensitive adhesive (PSA) or a combination thereof, and the optical adhesive layers 18 can be same or different.

In an embodiment, each of the positive A-plate and the negative A-plate is manufactured by a stretching process. The thickness of each of the stretched positive A-plate and negative A-plate is between 10 μm and 40 μm. The positive A-plate and the negative A-plate are same or different in thickness, which can be adjusted according to an actual application demand.

FIG. 2 is a schematic diagram of a dispersion curve of the anti-reflective film structure according to an embodiment of the present invention. The horizontal axis represents an incident wavelength, and the longitudinal axis represents a ratio of the in-plane phase differences respectively obtained with the specific incident wavelength and the incident wavelength of 550 nm. A solid line 32 is the optimum ideal curve of the inverse wavelength dispersion, a dashed line 34 is a dispersion curve of an existing one-piece inverse dispersed positive A-plate, and a dash-dotted line 36 is a relationship curve of the two-layer phase difference compensation film in the anti-reflective film structure 10 according to an embodiment of the present invention. It can be seen from FIG. 2 that the two-layer phase difference compensation film (i.e., the stacked positive A-plate and negative A-plate) in the anti-reflective film structure 10 provided by the present invention has the inverse wavelength dispersion with the quarter-wave phase difference, and is better than the one-piece inverse dispersed compensation film in functional effect. According to an experiment, the reflectivity of the two-layer phase difference compensation film in the anti-reflective film structure according to an embodiment of the present invention is between 0.5% a nd 2.0%, for example, 1.4%.

As mentioned above, the two-layer phase difference compensation film in the anti-reflective film structure according to an embodiment of the present invention has the advantages that compared with the existing one-piece inverse dispersed positive A-plate, the manufacturing cost is lower; and it does not need to be equipped with a positive C-plate with the large viewing angle compensation, so that the anti-reflective film structure features simple process and better production yield.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. An anti-reflective film structure, adapted to be applied to an organic light-emitting diode display panel, wherein the anti-reflective film structure comprises:
a quarter-wave phase difference compensation film with positive wavelength dispersion, the quarter-wave phase difference compensation film being arranged on the organic light-emitting diode display panel;
a half-wave phase difference compensation film with positive wavelength dispersion, the half-wave phase difference compensation film being arranged on a side of the quarter-wave phase difference compensation film away from the organic light-emitting diode display panel, and one of the quarter-wave phase difference compensation film and the half-wave phase difference compensation film being a positive A-plate and the other one of the quarter-wave phase difference compensation film and the half-wave phase difference compensation film being a negative A-plate; and
a linear polarizer, arranged on a side of the half-wave phase difference compensation film away from the quarter-wave phase difference compensation film.

2. The anti-reflective film structure according to claim 1, wherein the half-wave phase difference compensation film has a first optical axis angle, the quarter-wave phase difference compensation film has a second optical axis angle, and the first optical axis angle is different from the second optical axis angle.

3. The anti-reflective film structure according to claim 2, wherein the first optical axis angle is between 10° and 20°, and the second optical axis angle is between 70° and 80°.

4. The anti-reflective film structure according to claim 2, wherein the first optical axis angle is between 70° and 80°, and the second optical axis angle is between 10° and 20°.

5. The anti-reflective film structure according to claim 1, wherein an in-plane phase difference of the quarter-wave phase difference compensation film is between 90 nanometers and 140 nanometers, and an in-plane phase difference of the half-wave phase difference compensation film is between 180 nanometers and 280 nanometers.

6. The anti-reflective film structure according to claim 1, further comprising a plurality of optical adhesive layers respectively arranged between the quarter-wave phase difference compensation film and the organic light-emitting diode display panel, between the quarter-wave phase difference compensation film and the half-wave phase difference compensation film, and between the half-wave phase difference compensation film and the linear polarizer.

7. The anti-reflective film structure according to claim 6, wherein a material of the optical adhesive layer is selected from one of an optically clear adhesive, a liquid optically clear adhesive, and a pressure sensitive adhesive or a combination thereof.

8. The anti-reflective film structure according to claim 1, wherein the positive A-plate has a first thickness direction phase difference, the negative A-plate has a second thickness direction phase difference, and the sum of the first thickness direction phase difference and the second thickness direction phase difference is less than 10.

9. The anti-reflective film structure according to claim 1, wherein a thickness of each of the positive A-plate and the negative A-plate is between 10 microns and 40 microns.

10. The anti-reflective film structure according to claim 1, wherein each of the positive A-plate and the negative A-plate is manufactured by a stretching process.

11. The anti-reflective film structure according to claim 1, wherein the stacked positive A-plate and negative A-plate have quarter-wave inverse wavelength dispersion, match with the linear polarizer, and are applied to the organic light-emitting diode display panel, so that reflectivity is between 0.5% and 2.0%.
